(19) United States
(12) Patent Application Publication
(10) Pub. No.: US 2009/0240875 A1
(43) Pub. Date: Sep. 24, 2009

(54) CONTENT ADDRESSABLE MEMORY WITH HIDDEN TABLE UPDATE, DESIGN STRUCTURE AND METHOD

(76) Inventors: Albert M. Chu, Essex Junction, VT (US); Paul C. Parries, Wappingers Falls, NY (US); Daryl M. Seitzer, Essex Junction, VT (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 12/050,340

(22) Filed: Mar. 18, 2008

(51) Int. Cl. G11C 15/04; G11C 7/00

(52) U.S. Cl. 711/108; 365/49.17; 711/105

(57) ABSTRACT

Disclosed are embodiments of memory circuit having two discrete memory devices with two discrete memory arrays that store essentially identical data banks. The first device is a conventional memory adapted to perform all maintenance operations that require read functions (i.e., all update and refresh operations). The second device is a DRAM-based CAM device adapted to perform parallel search and overwrite operations only. Performance of overwrite operations by the second device occurs in conjunction with performance of maintenance operations by the first device so that corresponding memory cells in the two devices store essentially identical data values. Since the data banks in the memory devices are essentially identical and since maintenance and parallel search operations are not performed by the same device, the parallel search operations can be performed without interruption. Also disclosed are embodiments of an associated design structure and method.

### BACKGROUND

1. Field of the Invention

The embodiments of the invention generally relate to a content addressable memory, and, more particularly, to a content addressable memory with a hidden table update, a design structure for the memory and a method for updating a content addressable memory.

2. Description of the Related Art

High bandwidth router designs typically incorporate large ternary content addressable memory (TCAM) devices (i.e., CAM devices which store three logic values: high, low and don't care) for performing routing table lookups and packet classifications. Generally, these large TCAM devices are implemented with a static random access memory (SRAM) array because of the high performance qualities and static nature of the SRAM cells that form the SRAM array.

Recently, however, density and power requirements have led to an increasing interest in the use of TCAM devices implemented with a dynamic random access memory (DRAM) array rather than the SRAM array. Unfortunately, due to the read functions inherent in DRAM array maintenance operations (including but not limited to, refresh operations and update operations), a TCAM device implemented with a conventional DRAM array will have reduced performance and accessibility over a TCAM device implemented with an SRAM array. Specifically, DRAM cells require refresh (i.e., read and write-back) of the stored data due to capacitor leakage and, during DRAM array refresh operations, search operations are prohibited because the charge transfer that occurs during the read function temporarily destroys the data values in the DRAM cells until write-back occurs. Similarly, during DRAM array update operations, search operations are prohibited due to the multiple read and write functions required to reorder data values within the array. Thus, there is a need in the art for a CAM device that has the density and power advantages of a DRAM array, but avoids the performance and accessibility problems.

### SUMMARY

In view of the foregoing, disclosed herein are embodiments of a memory circuit that incorporates two discrete memory devices with two discrete, but corresponding, memory arrays for storing essentially identical data banks. The first memory device is a conventional memory device with a first array of memory cells (e.g., an SRAM or DRAM array). The first memory device performs maintenance operations in the first array, including but not limited to, all maintenance operations that require read functions (e.g., update and refresh operations). The second memory device is in communication with the first memory device and is a DRAM-based TCAM device with a second array of memory cells. The second memory device performs overwrite operations in the second array in conjunction with maintenance operations occurring in the first array so that corresponding memory cells in the two arrays store essentially identical data. The second memory device further performs parallel search operations (e.g., router table look-up operations) in the second array. Since the maintenance and search operations are performed by discrete memory devices, the parallel search operations can be performed without interruption.

More particularly, the memory circuit embodiments of the present invention can comprise a first memory device and, specifically, a conventional dense memory device with a first array of first memory cells. The first memory cells in the first array can comprise SRAM cells (e.g., six-transistor SRAM cells), DRAM or embedded DRAM cells (e.g., one-transistor/one capacitor DRAM cells) or any other suitable memory cells for a dense memory array. This first memory device can be adapted to perform all maintenance operations that require read operations. For example, the first memory device can be adapted to perform read and write operations in order to update data values in a data bank stored in the first memory cells of the first array. Furthermore, if the first memory device is a DRAM-based memory device, it can be adapted to perform the read and write-back operations required to refresh the DRAM cells in the first array.

The memory circuit embodiments can further comprise a second memory device and, specifically, a DRAM-based ternary content addressable memory (TCAM) device with a second array of second memory cells. Each second memory cell in the second array of the second memory device can correspond to a first memory cell in the first array of the first memory device. The second memory cells in the second array can comprise DRAM cells and, more specifically, can comprise six-transistor DRAM cells, each having two, one-transistor/one-capacitor, DRAM units and a four-transistor comparator circuit. This second memory device can be adapted to perform parallel search operations and, specifically, to perform the parallel search operations on a data bank stored in the second memory cells in the second array. Such parallel search operations can be performed in the same manner as in conventional TCAM devices. The second memory device can also be in communication with the first memory device and can be adapted to perform overwrite operations on the second memory cells in the second array so that corresponding first and second memory cells in the first and second memory arrays of the first and second memory devices, respectively, have identical data values. Such overwrite operations can be performed by the second memory device periodically, on-demand, and/or in conjunction with (e.g., immediately following in the same operation) the performance of maintenance operations by the first memory device so that the corresponding first and second memory cells have consistently identical data values. Consequently, such overwrite operations ensure that the same data banks are stored in both the first and second arrays of the first and second memory devices and, thereby, eliminate the need for separate update operations and refresh operations within the second memory device. That is, such overwrite operations can be used to effectively update and refresh the dynamic random access memory (DRAM) cells of the second array without requiring read operations in the second memory device that would interrupt the above-described parallel search operations.

The above-described memory circuit can be incorporated into a high bandwidth router design with power and density limitations. In such a router design, both the first and second memory devices would be in communication with a network processor (or network processor bridge, depending upon the embodiment). The first memory device would store data values for a router look-up table in the first memory cells of the first array. The first memory device would further be adapted to receive data value updates for the router look-up table from the network processor/network processor bridge and to perform the required maintenance operations to update (i.e., read and write) and, if necessary, refresh (i.e., read and write-back) the memory cells storing the data values for the router look-up table.

The second memory device would be in communication with the first memory device and would be adapted to perform the above-described overwrite operations in conjunction with the maintenance operations in the first memory device so as to virtually simultaneously update and refresh the data values stored in its corresponding router look-up table.

Thus, the overwrite operations ensure that the same data values for the same router look-up table are stored in the corresponding first and second memory cells of the first and second arrays, respectively. Finally, the second memory device would be adapted to receive search keys from the network processor/network processor bridge, to perform, in response to the search keys, parallel search operations on the router look-up table stored in the second array and to output the results of the parallel search operations to the network processor/network processor bridge. Since all maintenance operations on the router look-up table that require read operations (e.g., updates and refresh) are actually performed by the first memory device and since only overwrite and parallel search operations are performed by the second memory device, the parallel search operations performed on the router look-up table may be performed without interruption.

Also disclosed herein are embodiments of an associated method of updating and/or refreshing a content addressable memory without interrupting parallel search operations. The method embodiment can comprise providing a memory circuit, such as the memory circuit described in detail above. The method embodiments can further comprise performing, by the first memory device, of all maintenance operations that require read operations. Specifically, this process of performing all maintenance operations that require read operations can comprise receiving, by the first memory device, of data value updates for a data bank stored in the first memory cells of the first memory device. The process can further comprise performing any read and write operations required to apply the data value updates to the first memory cells in the first array. Additionally, if the first array comprises DRAM cells, the process can comprise performing the required refresh operations (i.e., read and write-back operations) for such DRAM cells.

The method embodiment can further comprise performing, by the second memory device, of parallel search operations on the second memory cells in the second array and outputting the results of the search operations. Such parallel search operations can be performed in the second array in the same manner as in conventional TCAM devices. For example, search keys can be received by the second memory device. In response to the search keys, parallel search operations can be performed by the second memory device on the data bank in the second array (e.g., on the router look-up table stored in the second memory cells of the second array) and the results (e.g., a match address from the router look-up table) can be output.

The method embodiments can also comprise performing, by the second memory device, of overwrite operations on the second memory cells in the second array so that corresponding first and second memory cells in the first and second memory arrays of the first and second memory devices, respectively, have identical data values. Specifically, the overwrite operations can be performed periodically, on-demand, and/or in conjunction (e.g., immediately following in the same operation) with the performance of the maintenance operations by the first memory device so that the corresponding first and second memory cells have consistently identical data values. Performing the overwrite operations in this manner ensures that the same data banks (i.e., the same router look-up tables) are stored in both the first and second arrays of the first and second memory devices and, thereby, eliminates the need for separate update operations and refresh operations within the second memory device. That is, such overwrite operations can be used to effectively update and refresh the dynamic random access memory (DRAM) cells of the second array without requiring read operations that would interrupt the parallel search operations (i.e., the overwrite operations allow the parallel search operations to be performed in the second array without interruptions caused by the performance of maintenance operations).

Also disclosed is a design structure for the above-described memory circuit, the design structure being embodied in a machine readable medium.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments without departing from the spirit thereof, and the embodiments include all such changes and modifications.

### BRIEF DESCRIPTION OF THE DRAWINGS

The embodiments of the invention will be better understood from the following detailed description with reference to the drawings, in which:

FIG. 1 is a block diagram illustrating an embodiment of the memory circuit of the present invention;

FIG. 2 is a schematic diagram illustrating a 6T SRAM cell that can be incorporated into the first memory device of FIG. 1;

FIG. 3 is a schematic diagram illustrating a 1T/1C DRAM cell that can alternatively be incorporated into the first memory device of FIG. 1;

FIG. 4 is a schematic diagram illustrating a 6T DRAM cell that can be incorporated into the second memory device of FIG. 1;

FIG. 5 is a flow diagram illustrating an embodiment of the method of the present invention; and

FIG. 6 is a flow diagram of a design process used in semiconductor design, manufacture, and/or test.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, high bandwidth router designs typically incorporate large ternary content addressable memory (CAM) devices (i.e., CAM devices which store three logic values: high, low and don't care) for performing routing table lookups and packet classifications to determine the next hop for a received packet. U.S. Pat. No. 6,574,701, issued on Jun. 3, 2003 to Krishna et al. and incorporated herein by reference, describes the function and structure of a conventional TCAM device. In general, a network processor or network processor bridge will build a search key based on header fields in a received packet. The search key is input into the TCAM through a search key port and the TCAM runs a parallel search operation. If a match is found, the address for the matched data is output back to the network processor/network processor bridge through a results port. The CAM entry address will corresponds to the address of an entry in an associated memory from which the location of the next hop is read. Additionally, updates to a TCAM (e.g., additions or deletions of table entries) are entered through an update port.

TCAM devices often incorporate a static random access memory (SRAM) array because of the high performance qualities and static nature of the SRAM cells that form such an array. However, such SRAM-based TCAM devices have significant power and density limitations, due to the high number of transistors required in each cell. For example, an SRAM array in a typical SRAM-based TCAM device uses 16-transistor SRAM cells (i.e., two 6-transistor SRAM cells and a 4-transistor comparator circuit). Recently, these density and power limitations have led to an increasing interest in the use of CAM devices that incorporate a dynamic random access memory (DRAM) array rather than the SRAM array. A DRAM array in a DRAM-based TCAM device would only require six transistors (i.e., two 1-transistor DRAM cells and a 4-transistor comparator circuit). Unfortunately, due to the read function inherent in DRAM array maintenance operations, including but not limited to, refresh operations and update operations, a DRAM-based TCAM device will have reduced performance and accessibility over a SRAM-based TCAM device. Specifically, DRAM cells require refresh (i.e., read and write-back) of the stored data due to capacitor leakage and during DRAM array refresh operations, search operations are prohibited because the charge transfer that occurs during the read function temporarily destroys the data values in the DRAM cells until write-back occurs. Similarly, during DRAM array update operations, search operations are prohibited due to the multiple read and write functions required to reorder data values within the array. Thus, there is a need in the art for a CAM device that has the density and power advantages of a DRAM array, but avoids the performance and accessibility problems.

In view of the foregoing, disclosed herein are embodiments of a memory circuit that incorporates two discrete memory devices with two discrete, but corresponding, memory arrays for storing essentially identical data banks. The first memory device is a conventional memory device with a first array of memory cells (e.g., an SRAM or DRAM array). The first memory device performs maintenance operations in the first array, including but not limited to, all maintenance operations that require read functions (e.g., update and refresh operations). The second memory device is in communication with the first memory device and is a DRAM-based TCAM device with a second array of memory cells. The second memory device performs overwrite operations in the second array in conjunction with maintenance operations occurring in the first array so that corresponding memory cells in the two arrays store essentially identical data. The second memory device further performs parallel search operations (e.g., router table look-up operations) in the second array. Since the maintenance and search operations are performed by discrete memory devices, the parallel search operations can be performed without interruption.

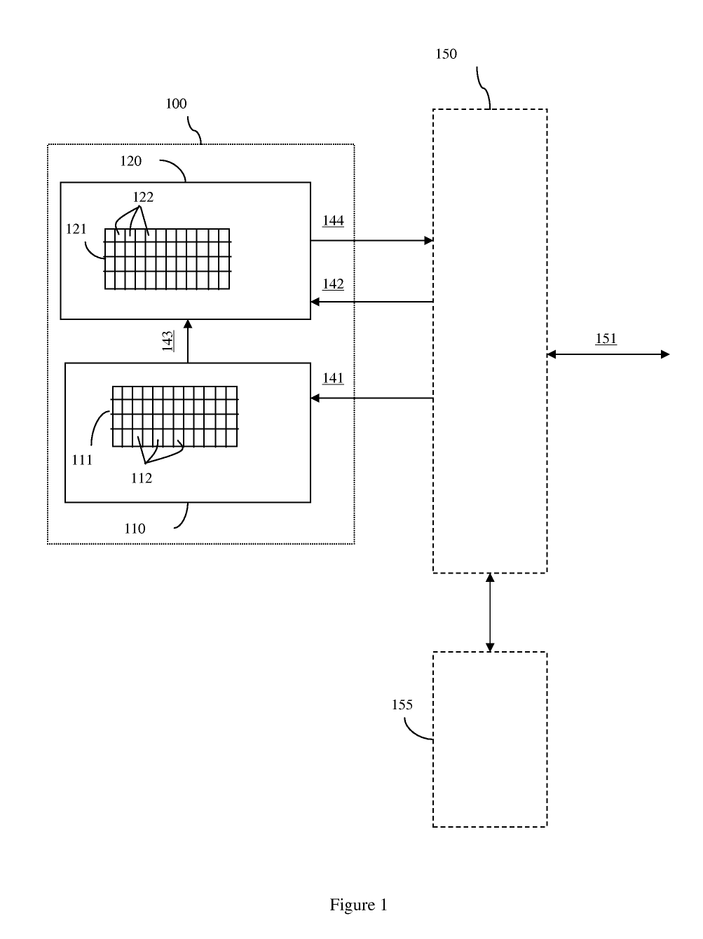

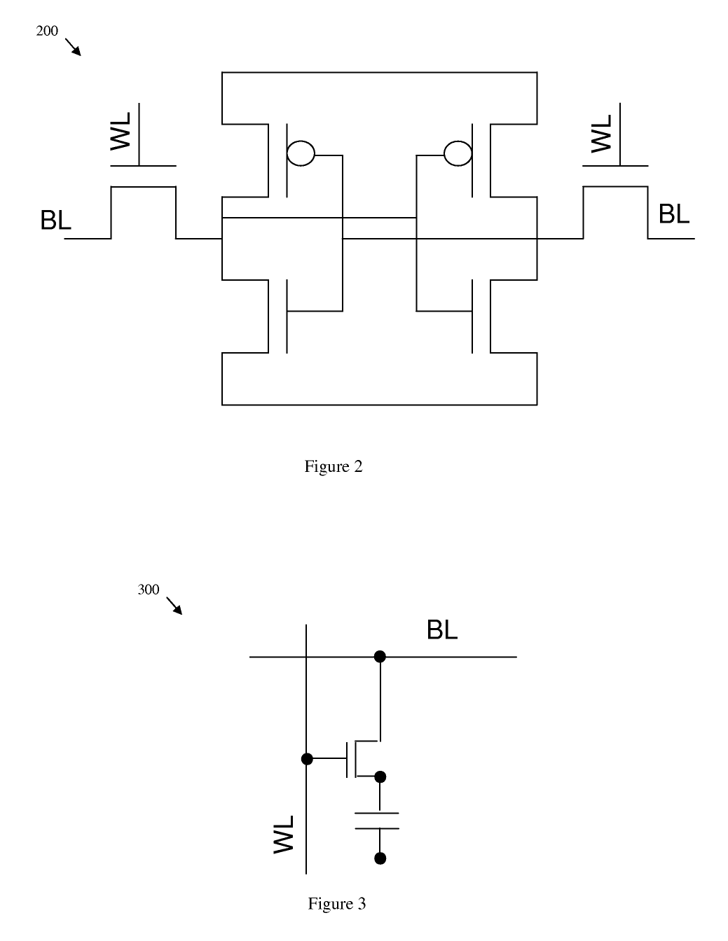

More particularly, referring to FIG. 1, the memory circuit 100 embodiments of the present invention can comprise a first memory device 110 (e.g., a conventional dense memory array) with a first array 111 of first memory cells 112. The first memory cells 112 of the first array 111 can comprise any suitable memory cell configuration for a dense memory array. For example, the first memory cells 112 can comprise SRAM cells, such as conventional 6T SRAM cells 200 with two pull-up, two pull-down and two pass-gate transistors, as illustrated in FIG. 2. Alternatively, the first memory cells 112 can comprise DRAM or embedded DRAM cells, such as conventional DRAM cells 300 with one pass transistor and one data storage capacitor, as illustrated in FIG. 3.

This first memory device 110 can be adapted to perform conventional memory operations on the data bank stored in the first memory cells 112 of the first array 111. More particularly, the first memory device 110 can be adapted to perform all maintenance operations that require read operations. For example, the first memory device 110 can be adapted to receive data value updates (e.g., instructions to add or remove data values) via update port 141 for a data bank stored in the first memory cells 112. The first memory device 110 can further be adapted to perform the read and write operations required to update the data values accordingly. Those skilled in the art will recognize that updates to the data values in a data bank (e.g., to a router look-up table) stored in a CAM typically require both read and write operations because if new data values are added and/or if old data values are removed, the data entries must be re-ordered. Finally, if the first memory device 110 is a DRAM-based memory device (i.e., if the first memory device 110 incorporates DRAM cells 300, as illustrated in FIG. 3), it can further be adapted to perform the read and write-back operations required to refresh such DRAM cells 300.

The memory circuit 100 embodiments can further comprise a second memory device 120 and, specifically, a DRAM-based ternary content addressable memory (TCAM) device, having a second array 121 of second memory cells 122. Each second memory cell 122 in the second array 121 of the second memory device 120 can correspond to a first memory cell 112 in the first array 111 of the first memory device 110. Additionally, the second memory cells 122 of the DRAM-based TCAM device can comprise DRAM cells appropriate for device.

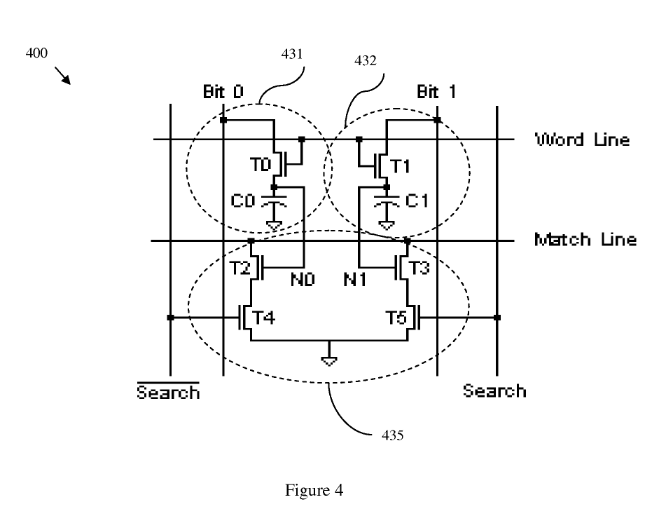

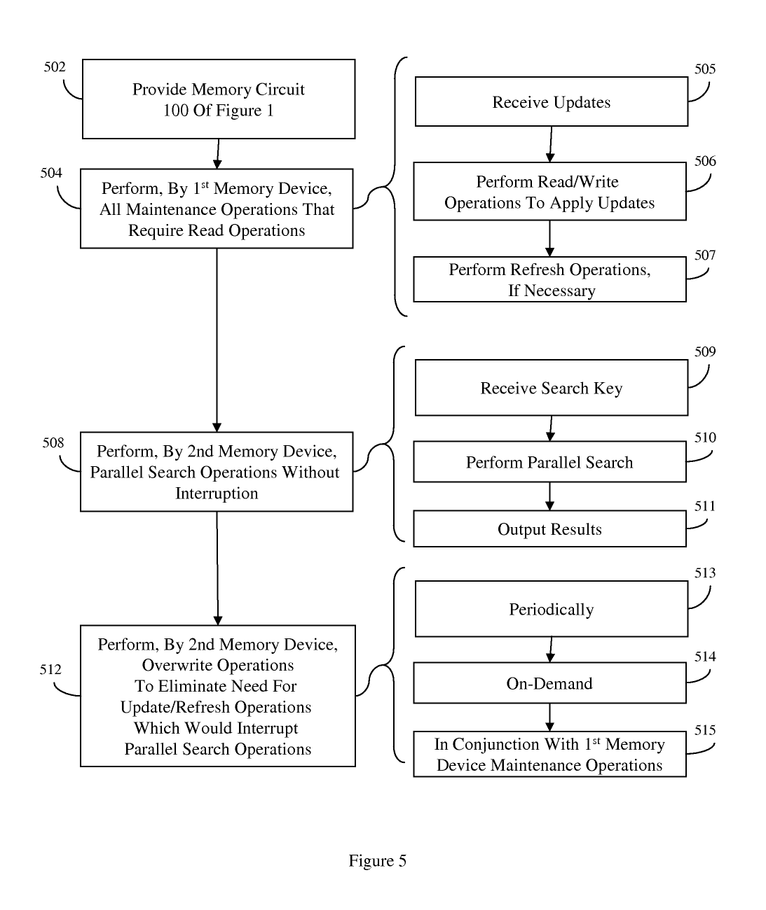

FIG. 4 illustrates an exemplary DRAM cell 400 that can be incorporated into the second array 121 of the DRAM-based TCAM device 120 of FIG. 1. This DRAM cell 400 can comprise two, one-transistor/one-capacitor, DRAM units 431, 432, each comprising a capacitor C0, C1 for storing data and a pass transistor T0, T1 for writing data to the capacitor C0, C1. Each DRAM cell 400 can further comprises an XNOR comparator circuit 435 having four transistors (T2-T5) for comparing data values to search keys. Thus, the DRAM cell 400 is a six-transistor DRAM cell.

The second memory device 120 can be adapted to perform parallel search operations and overwrite operations only (i.e., it can be prohibited from performing read operations). Specifically, this second memory device 120 can be adapted to perform parallel search operations on a data bank stored in the second memory cells 122 in the second array 121. Such parallel search operations can be performed in the same manner as in conventional DRAM-based TCAM devices. That is, during a parallel search operation, a search key can be received by the second memory device 120 via a search key port 142. In response to the search key, each memory cell 122 in the memory array 122 is accessed in parallel and compared (e.g., by its comparator circuit 435 of FIG. 4) to the search key. If a match is found at any location in the array 121, a match signal is generated and output via results port 144.

In addition, the second memory device 120 can be in communication with the first memory device 110 via overwrite port 143 and can be adapted to perform overwrite operations on the second memory cells 122 in the second array 121 so that corresponding first and second memory cells 112, 122 in the first and second memory arrays 111, 121 of the first and second memory devices 110, 120, respectively, have identical data values. In other words the data from the first memory array 111 in the conventional first memory device 110 is written to the second memory array 121 of the write/search-only second memory device 120. Such overwrite operations can be performed by the second memory device 120 periodically, on-demand, and/or in conjunction with (e.g., immediately following in the same operation) the performance of maintenance operations by the first memory device 110 so that the corresponding first and second memory cells 112, 122 have consistently identical data values. Consequently, such overwrite operations ensure that the same data banks are stored in both the first and second arrays 111, 121 of the first and second memory devices 110, 120 and, thereby, eliminate the need for separate update operations and refresh operations within the second memory device 120. That is, such overwrite operations can be used to effectively update and refresh the dynamic random access memory (DRAM) cells 122 of the second array 121 without requiring read operations in the second memory device 120 that would interrupt the above-described parallel search operations.

For example, referring to FIGS. 3 and 4 in combination with FIG. 1, in one particular embodiment of the memory circuit 100 of the present invention, the first memory cells 112 of the first array 111 in the first memory device 110 and the second memory cells 122 of the second memory array 121 in the second memory device 120 can both comprise DRAM cells. Specifically, the first array 111 of the first memory device 110 can comprise one-transistor/one-capacitor DRAMs cells 300, as illustrated in FIG. 3 and the second array 121 of the second memory device 120 can comprise six-transistor DRAM cells 400, as illustrated in FIG. 4. Since all DRAM cells require refreshing, the first memory device 110 can be adapted to perform its maintenance operations not only to update, but to also refresh, the DRAM cells 300 incorporated into the first array 111. Furthermore, the second memory device 120 can be adapted to perform its overwrite operations in the second array 121 in conjunction with (e.g., immediately following in the same operation) performance by the first memory device 110 of update and refresh maintenance operations in order to virtually simultaneously update and refresh the DRAM cells 400 of the second array 121 with the DRAM cells 300 of the first array 111. Performing the maintenance and overwrite operations in this manner ensures that the corresponding first and second memory cells 112, 122 have identical data values at virtually all times without requiring read operations in the second array 121 that interrupt the parallel search operations.

Since all maintenance operations that require read operations are performed by the first memory device 110 and since only overwrite and parallel search operations are performed by the second memory device 120, read-related limitations (e.g., bitcell stability, Ion/Ioff ratio, development of bitline differential or charge sharing ratio) on the maximum number of second memory cells 122 per bitline that can be incorporated into the second array 121 are avoided. In fact, this maximum number of second memory cells 122 per bitline is limited only by write access time, thereby allowing for much greater array utilization. Additional benefits, which are related to overall memory circuit 100 size and density, can also be achieved with the present invention. Specifically, while the present invention requires two discrete memory devices 110, 120, having two discrete memory arrays 111, 121, the combined number of transistors required for the two arrays 111, 121, is less than that required by prior art SRAM-based TCAM devices. For example, as discussed above, the first memory cells 112 of the first array 111 of the first memory device 110 can comprise one-transistor/one capacitor DRAM cells 300 of FIG. 3 or six-transistor SRAM cells 200 of FIG. 2. The second memory cells 122 of the second array 121 of the second memory device 120 can comprise six-transistor DRAM cells 400 of FIG. 4. Thus, regardless of whether DRAM or SRAM cells are used in the first array 111, the combined number of transistors in any two corresponding first and second memory cells 112, 122 from the two arrays 111, 121 will be equal to twelve or less and, therefore, will be less that the sixteen transistors used in the SRAM cells of prior art SRAM-based TCAM devices.

The above-described memory circuit 100 can be incorporated into any structure requiring a TCAM device with power and density design limitations. For example, referring again to FIG. 1, the above-described memory circuit 100 can be incorporated into a high bandwidth router design with power and density limitations. In such a router design, the first memory device 110 and second memory device 120 would both be in communication with a network processor 150 (or with a network processor bridge, depending upon the router design). The first memory device 110 would store data values for a router look-up table in the first memory cells 112 of the first array 111. The first memory device 110 would further be adapted to receive data value updates for the router look-up table from the network processor/network processor bridge 150 via data value update port 141 and to perform the required maintenance operations to update (i.e., read and write) and, if necessary, refresh (i.e., read and write-back) the memory cells 112 storing the data values for the router look-up table.

The second memory device 120 would be in communication via overwrite port 143 with the first memory device 110 and would be adapted to perform the above-described overwrite operations in conjunction with the maintenance operations in the first memory device 110 so as to virtually simultaneously update and refresh the data values stored in its corresponding router look-up table. Thus, the overwrite operations ensure that the same data values for the same router look-up table are stored in the corresponding first and second memory cells 112, 122 of the first and second arrays 111, 121, respectively. Additionally, as mentioned above, the second memory device 120 would be in communication with the network processor/the network processor bridge 150 and would be adapted to receive search keys from the network processor/network processor bridge 150 over search key port 142. Each search key is generated by the network processor/network processor bridge 150 based on information contained in the header of a received packet 151. The second memory device 120 would further be adapted to perform, in response to the search keys, parallel search operations on the router look-up table stored in the second array 121. Since all maintenance operations on the router look-up table that require read operations (e.g., updates and refresh) are actually performed by the first memory device 110 and since only overwrite and parallel search operations are performed by the second memory device 120, the parallel search operations of the router look-up table may be performed without interruption. Once parallel search operations are completed, the results are (e.g., match addresses) are output to the network processor/network processor bridge 150 over the results port 144. A match address from the CAM 120 indicates and address in an associated memory 155 from which the network processor/network processor bridge 150 will read to determine the next hop for the received packet.

Referring to FIG. 5 in combination with FIG. 1, disclosed herein are embodiments of an associated method of updating and/or refreshing a content addressable memory circuit without interrupting parallel search operations. The method embodiment can comprise providing a memory circuit, such as the memory circuit 100 described-above and illustrated in FIG. 1, with a first memory device 110 in communication with a second memory device 120 (502). Specifically, the first memory device 110 of the provided memory circuit 100 can comprise a first array 111 (i.e., a dense memory array) comprising first memory cells 112 (e.g., six-transistor SRAM cells 200 of FIG. 2, one-transistor/one-capacitor DRAM cells 300 of FIG. 3, or any other appropriate memory cells for a dense memory array). The second memory device 120 of the provided memory circuit 100 can comprise a DRAM-based ternary content addressable memory (TCAM) device with a second array 121 of second memory cells 122 (e.g., six transistor DRAM cells 400, as illustrated in FIG. 4). Additionally, each second memory cell 122 in the second array 121 can correspond to a first memory cell 112 in the first array 111.

The method embodiments can further comprise performing, by the first memory device 110, of all maintenance operations that require read operations (504). This process (504) can comprise receiving, by the first memory device 110, of data value updates for a data bank stored in the first memory cells 112 of the first memory device 110 (505). For example, the data value updates can be received from a network processor 150 (or from a network processor bridge, depending upon the embodiment) over an updates port 141. These updates can comprise instructions to add or delete entries from a router look-up table that is stored in memory device 110. The process of performing all maintenance operations that require read operations can further comprise performing any read and write operations required to apply the data value updates to the first memory cells 112 in the first array 111 (506). Those skilled in the art will recognize that updates to a data bank, such as a router look-up table, stored in a CAM typically require both read and write operations because stored data values must be re-ordered if new data values are added and/or if old data values are removed. Additionally, if the first memory cells 112 of the first array 111 of the first memory device 110 comprise DRAM cells, the process of performing all maintenance operations that require read operations can further comprise performing the required refresh operations for the DRAM cells (i.e., read and write-back operations) (507).

The method embodiment can further comprise performing, by the second memory device 120, of parallel search operations on the second memory cells 122 in the second array 121 and outputting the results of the search operations (508). Such parallel search operations can be performed in the second array 121 in the same manner as in conventional TCAM devices. For example, search keys for a data bank (e.g., for a router look-up table) stored in the second memory device 120 can be received by the second memory device 120 (509). Such search keys can be generated, for example, based on headers in a received packet and can be received over a search key port 142 either directly from a network processor or from a network processor bridge 150. In response to the search keys, parallel search operations can be performed by the second memory device 120 on the data bank in the second array 121 (e.g., on the router look-up table) (510). That is, each memory cell 122 in the memory array 122 can be accessed in parallel and compared to the search key. If a match is found at any location in the array 121, results (e.g., a match signal indicating the matched address from the router look-up table) are generated. The results can be output via a results port 144 back to the network processor/network processor bridge 150. A match address from the CAM 120 corresponds to an address in an associated memory 155. The entry at this associated memory address is then read by the network processor/network processor bridge 150 to determine the next hop for the received packet.

The method embodiments can also comprise performing, by the second memory device 120, of overwrite operations on the second memory cells 122 in the second array 121 so that corresponding first and second memory cells in the first and second memory arrays 111, 121 of the first and second memory devices 110, 120, respectively, have identical data values (512). Specifically, the overwrite operations can be performed periodically, on-demand, and/or in conjunction (e.g., immediately following in the same operation) with the performance of maintenance operations by the first memory device 110 so that the corresponding first and second memory cells 112, 122 have consistently identical data values (513-515). Performing the overwrite operations in this manner ensures that the same data banks (i.e., the same router look-up tables) are stored in both the first and second arrays 111, 121 of the first and second memory devices 110, 120 and, thereby, eliminates the need for separate update operations and refresh operations within the second memory device 120. That is, such overwrite operations can be used to effectively update and refresh the dynamic random access memory (DRAM) cells of the second array 121 without requiring read operations that would interrupt the parallel search operations (i.e., the overwrite operations allow the parallel search operations to be performed in the second array 121 without interruptions caused by the performance of maintenance operations). Thus, the memory circuit 100 provides update/refresh operations that are hidden from the parallel search operations.

For example, in one particular embodiment of the method, the first memory cells 112 of the first array 111 in the first memory device 110 and the second memory cells 122 of the second memory array 121 in the second memory device 120 can both comprise dynamic random access memory (DRAM) cells (e.g., one-transistor and six-transistor DRAM cells, respectively). Since all DRAM cells require refreshing, the process (504) of performing, by the first memory device 110, of all maintenance operations that require read operations can comprise performing such maintenance operations not only to update (506), but to refresh (507), the DRAM cells of first array 111. Furthermore, the process (512) of performing, by the second memory device 120, of overwrite operations can comprise performing the overwrite operations in conjunction with (e.g., immediately following in the same operation) the performance, by the first memory device, of the update and refresh maintenance operations in the first array 111 (515) so as to virtually simultaneously update and refresh the DRAM cells 122 of the second array 121 with the DRAM cells 112 of the first array 111. Performing the maintenance and overwrite operations (504 and 512) in this manner ensures that the corresponding first and second memory cells 112, 122 have identical data values at virtually all times without actually requiring read operations in the second array 121, which would interrupt the parallel search operations (508). Finally, since all maintenance operations that require read operations are performed (at process 504) by the first memory device 110 and since only overwrite and parallel search operations are performed (at processes 508 and 512), by the second memory device 120, read-related limitations (e.g., bitcell stability, Ion/Ioff ratio, development of bitline differential or charge sharing ratio) on the maximum number of second memory cells 122 per bitline that can be incorporated into the second array 121 are avoided. As discussed above, this maximum number of second memory cells 122 per bitline is only limited only by write access time, thereby allowing for much greater array utilization.

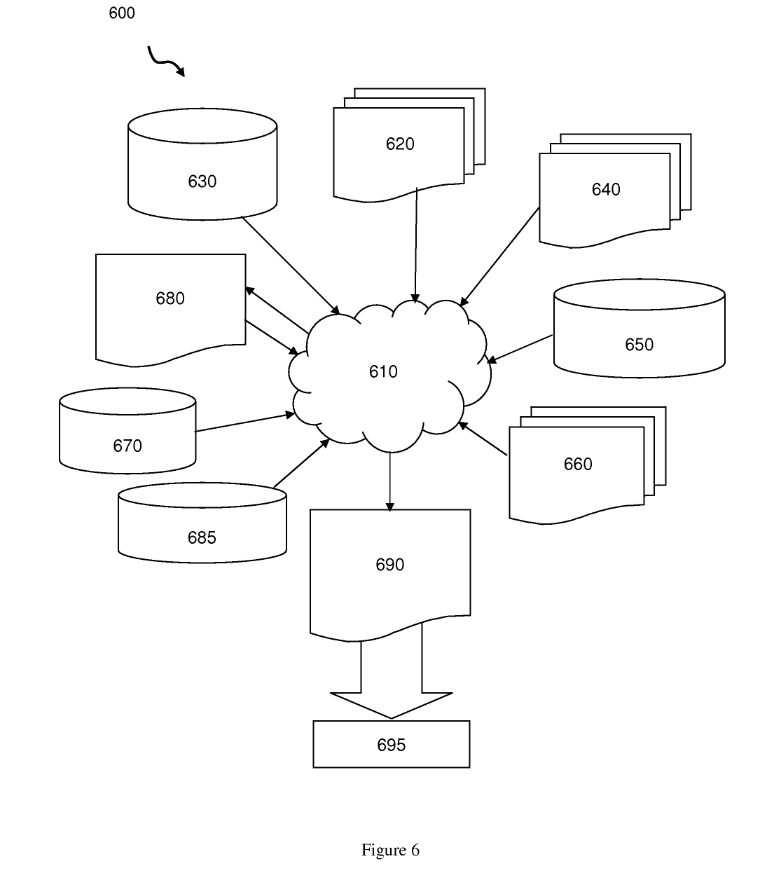

Also disclosed is a design structure for the above-described memory circuit 100, the design structure being embodied in a machine readable medium. More specifically, FIG. 6, shows a block diagram of an exemplary design flow 600 used for example, in semiconductor design, manufacturing, and/or test. Design flow 600 may vary depending on the type of IC being designed. For example, a design flow 600 for building an application specific IC (ASIC) may differ from a design flow 600 for designing a standard component. Design structure 620 is preferably an input to a design process 610 and may come from an IP provider, a core developer, or other design company or may be generated by the operator of the design flow, or from other sources. Design structure 620 comprises an embodiment of the invention as shown in the diagram of the memory circuit 100 in FIG. 1 in the form of schematics or HDL, a hardware-description language (e.g., Verilog, VHDL, C, etc.). Design structure 620 may be contained on one or more machine readable medium. For example, design structure 620 may be a text file or a graphical representation of an embodiment of the invention as shown in the diagram of the memory circuit 100 in FIG. 1. Design process 610 preferably synthesizes (or translates) an embodiment of the invention, as shown in the diagram of the memory circuit 100 in Figure, into a netlist 680, where netlist 680 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 680 is resynthesized one or more times depending on design specifications and parameters for the circuit.

Design process 610 may include using a variety of inputs; for example, inputs from library elements 630 which may house a set of commonly used elements, circuits, and devices, including models, layouts, and symbolic representations, for a given manufacturing technology (e.g., different technology nodes, 32 nm, 45 nm, 90 nm, etc.), design specifications 640, characterization data 650, verification data 660, design rules 670, and test data files 685 (which may include test patterns and other testing information). Design process 610 may further include, for example, standard circuit design processes such as timing analysis, verification, design rule checking, place and route operations, etc. One of ordinary skill in the art of integrated circuit design can appreciate the extent of possible electronic design automation tools and applications used in design process 610 without deviating from the scope and spirit of the invention. The design structure of the invention is not limited to any specific design flow.

Design process 610 preferably translates an embodiment of the invention, as shown in the diagram of the memory circuit 100 in FIG. 1, along with any additional integrated circuit design or data (if applicable), into a second design structure 690. Design structure 690 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 690 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention, as shown in the diagram of the memory circuit 100 in FIG. 1. Design structure 690 may then proceed to a stage 695 where, for example, design structure 690: proceeds to tape-out, is released to manufacturing, is released to a mask house, is sent to another design house, is sent back to the customer, etc.

Therefore, disclosed above are embodiments of a memory circuit that incorporates two discrete memory devices with two discrete, but corresponding, memory arrays for storing essentially identical data banks. The first memory device is a conventional memory device with a first array of memory cells (e.g., an SRAM or DRAM array). The first memory device performs maintenance operations in the first array, including but not limited to, all maintenance operations that require read functions (e.g., update and refresh operations). The second memory device is in communication with the first memory device and is a DRAM-based TCAM device with a second array of memory cells. The second memory device performs overwrite operations in the second array in conjunction with maintenance operations occurring in the first array so that corresponding memory cells in the two arrays store essentially identical data. The second memory device further performs parallel search operations (e.g., router table look-up operations) in the second array. Since the maintenance and search operations are performed by discrete memory devices, the parallel search operations can be performed without interruption. Also disclosed are embodiments of an associated design structure and method.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the invention has been described in terms of embodiments, those skilled in the art will recognize that the embodiments can be practiced with modification within the spirit and scope of the appended claims.

What is claimed is:

1. A memory circuit comprising:
a first memory device comprising a first array of first memory cells, wherein said first memory device is adapted to perform all maintenance operations that require read operations; and
a second memory device comprising a second array of second memory cells with each one of said second memory cells corresponding to one of said first memory cells,
wherein said second memory device comprises a content addressable memory (CAM) device adapted to perform parallel search operations on said second memory cells in said second array, and
wherein said second memory device is further in communication with said first memory device and adapted to perform overwrite operations on said second memory cells in said second array so that corresponding first and second memory cells have identical data values.

2. The memory circuit according to claim 1, all the limitations of which are incorporated by reference, wherein said maintenance operations comprise read and write operations for updating data values in said first memory cells in said first array.

3. The memory circuit according to claim 1, all the limitations of which are incorporated by reference, wherein said second memory cells comprise dynamic random access memory (DRAM) cells.

4. The memory cells of claim 3, all the limitations of which are incorporated by reference, wherein said overwrite operations effectively update and refresh said dynamic random access memory (DRAM) cells of said second array without requiring read operations that interrupt said parallel search operations.

5. The memory circuit according to claim 1, all the limitations of which are incorporated by reference, wherein said second memory array is further adapted to perform said overwrite operations at least one of periodically, on-demand, and in conjunction with performance of said maintenance operations so that said corresponding first and second memory cells have consistently identical data values.

6. The memory circuit according to claim 1, all the limitations of which are incorporated by reference, wherein said first memory cells and said second memory cells comprise dynamic random access memory (DRAM) cells,
wherein said first memory device is adapted to perform said all maintenance operations that require read operations in order to both update and refresh said dynamic random access memory (DRAM) cells of said first array, and
wherein said second memory device is further adapted to perform said overwrite operations in said second array in conjunction with performance by said first memory device of said all maintenance operations that require read operations in order to virtually simultaneously update and refresh said dynamic random access memory (DRAM) cells of said second array with said dynamic random access memory (DRAM) cells of said first array so that said corresponding first and second memory cells have said identical data values at virtually all times without requiring read operations in said second array that interrupt said parallel search operations.

7. The memory circuit according to claim 1, all the limitations of which are incorporated by reference, wherein said second memory cells comprise six-transistor dynamic random access memory (DRAM) cells.

8. The memory circuit according to claim 1, all the limitations of which are incorporated by reference, wherein said first memory cells comprise one of dynamic random access memory (DRAM) cells and static random access memory (SRAM) cells.

9. The memory circuit according to claim 1, all the limitations of which are incorporated by reference, wherein due to performance by said first memory device of said all maintenance operations that require read operations, read-related limitations on a maximum number of said second memory cells per bitline that can be incorporated into said second array are avoided.

10. The memory circuit according to claim 2, all the limitations of which are incorporated by reference, wherein said data values comprise data values for a look-up table,
wherein said first memory device is in communication with one of a network processor and a network processor bridge and is further adapted to receive data value updates for said look-up table from said one of said network processor and said network processor bridge, and
wherein said second memory device is in communication with said one of network processor and said network processor bridge and is adapted to receive search keys, to perform said parallel search operations in response to said search keys and to output results of said parallel search operations to said one of said network processor and said network processor bridge.

11. A method for updating a content addressable memory, said method comprising:
providing a first memory device in communication with a second memory device, wherein said first memory device comprises a first array of first memory cells and said second memory device comprises a second array of second memory cells with each one of said second memory cells corresponding to one of said first memory cells;
performing, by said first memory device, of all maintenance operations that require read operations;
performing, by said second memory device, of overwrite operations on said second memory cells in said second array so that corresponding first and second memory cells have identical data values;
performing, by said second memory device, of parallel search operations on said second memory cells in said second array without interruptions caused by said performing of said maintenance operations; and
outputting results of said parallel search operations.

12. The method according to claim 11, all the limitations of which are incorporated by reference, wherein said performing, by said first memory device, of said all maintenance operations that require read operations comprises performing read and write operations in order to apply data value updates to said first memory cells in said first array.

13. The method according to claim 11, all the limitations of which are incorporated by reference, wherein said second memory cells comprise dynamic random access memory (DRAM) cells and wherein said performing, by said second memory device, of said overwrite operations comprises performing said overwrite operations so as to effectively update and refresh said dynamic random access memory (DRAM) cells of said second array without requiring read operations that interrupt said parallel search operations.

14. The method according to claim 11, all the limitations of which are incorporated by reference, wherein said performing, by said second memory device, of said overwrite operations comprises performing said overwrite operations at least one of periodically, on-demand, and in conjunction with said performing, by said first memory device, of said all maintenance operations that require read operations so that said corresponding first and second memory cells have consistently identical data values

15. The method according to claim 11, all the limitations of which are incorporated by reference, wherein said first memory cells and said second memory cells comprise dynamic random access memory (DRAM) cells,
wherein said performing, by said first memory device, of said all maintenance operations that require read operations comprises both updating and refreshing said dynamic random access memory (DRAM) cells of said first array, and
wherein said performing, by said second memory device, of said overwrite operations comprises performing said overwrite operations in said second array in conjunction with said maintenance operations in said first array in order to virtually simultaneously update and refresh said dynamic random access memory (DRAM) cells of said second array with said dynamic random access memory (DRAM) cells of said first array so that said corresponding first and second memory cells have said identical data values at virtually all times without requiring read operations in said second array that interrupt said parallel search operations.

16. The method according to claim 11, all the limitations of which are incorporated by reference, wherein, said performing, by said first memory device, of said all maintenance operations that require read operations avoids read-related limitations on a maximum number of said second memory cells per bitline that can be incorporated into said second array.

17. The method according to claim 12, all the limitations of which are incorporated by reference, further comprising:
receiving, by said first memory device, of said data value updates from one of a network processor and a network processor bridge, wherein said data values updates are for a router look-up table stored in said first memory device and said second memory device; and
receiving, by said second memory device, of search keys from said one of said network processor and said network processor bridge, wherein said performing of said parallel search operations is in response to said search keys and wherein said outputting of said results comprises outputting an address from said router look-up table to said one of said network processor and said network processor bridge.

18. A design structure embodied in a machine readable medium, said design structure comprising a memory circuit comprising:
a first memory device comprising a first array of first memory cells, wherein said first memory device is adapted to perform all maintenance operations that require read operations; and
a second memory device comprising a second array of second memory cells with each one of said second memory cells corresponding to one of said first memory cells,
wherein said second memory device comprises a content addressable memory (CAM) device adapted to perform parallel search operations on said second memory cells in said second array, and
wherein said second memory device is further in communication with said first memory device and adapted to perform overwrite operations on said second memory cells in said second array so that corresponding first and second memory cells have identical data values.

19. The design structure according to claim 18, all the limitations of which are incorporated by reference, wherein said design structure comprises a netlist.

20. The design structure according to claim 18, all the limitations of which are incorporated by reference, wherein said design structure resides on storage medium as a data format used for the exchange of layout data of integrated circuits.
